(19) United States
(12) Patent Application Publication
(10) Pub. No.: US 2026/0331160 A1
(43) Pub. Date: Oct. 22, 2026

(54) VOLTAGE DETECTION CIRCUIT, SEMICONDUCTOR MEMORY DEVICE, AND CONTROL METHOD OF SEMICONDUCTOR MEMORY DEVICE

(71) Applicant: Winbond Electronics Corp., Taichung City (TW)

(72) Inventor: Takahiko SATO, Yokohama (JP)

(73) Assignee: Winbond Electronics Corp., Taichung City (TW)

(21) Appl. No.: 19/644,971

(22) Filed: Apr. 10, 2026

(30) Foreign Application Priority Data
Apr. 21, 2025 (JP) 2025-069280

(51) Int. Cl. G11C 11/4072; G11C 11/4074; H03K 19/00

(52) U.S. Cl. CPC G11C 11/4072; G11C 11/4074; H03K 19/0005

(57) ABSTRACT

Provided is a voltage detection circuit designed for an integrated semiconductor memory device. The voltage detection circuit includes a control unit that operates to monitor and detect the startup voltage level of the semiconductor memory device. This detection process is executed based on a specific calibration result that is internally obtained during the initialization of the semiconductor memory device.

### CROSS REFERENCE TO RELATED APPLICATIONS

This application claims priority of Japanese patent application No. 2025-069280, filed Apr. 21, 2025, the entirety of which is incorporated by reference herein.

### TECHNICAL FIELD

The present disclosure relates to a voltage detection circuit, a semiconductor memory device, and a method for controlling a semiconductor memory device.

### BACKGROUND

Conventionally, certain semiconductor memory devices, such as a Dynamic Random Access Memory (DRAM), are configured to read initial setting information from an internal non-volatile memory device when an external power supply is applied. This initial setting information is used to configure operating conditions of the semiconductor memory device, for instance, an internal operating voltage thereof (for example, Japanese Unexamined Patent Application Publication No. 2001-176290).

Semiconductor memory device typically includes a voltage detection circuit that detects the voltage of the external power supply. The voltage detection unit is configured to assert a trigger signal (e.g., by transitioning to a high logic level) to initiate a startup operation of the semiconductor memory device, such as reading the initial setting information from the non-volatile memory device, when the detected voltage reaches a predetermined startup voltage level.

However, the startup voltage level at which the trigger signal is asserted can deviate from a desired level due to factors such as variations in the manufacturing conditions of the semiconductor memory device and the operating environment. Consequently, variations in the startup voltage level of the device can occur. For instance, if the trigger signal is asserted when the external power supply voltage has not yet reached the desired level, the initial setting information may not be read correctly from the non-volatile memory device. In such a case, the initialization based on this information is not performed properly, which can potentially lead to malfunctions or failures of the semiconductor memory device.

### BRIEF SUMMARY

The present disclosure provide a voltage detection circuit, a semiconductor memory device, and a method for controlling the semiconductor memory device that are capable of suppressing variations in the startup voltage level of the semiconductor memory device, which may be caused by factors including variations in manufacturing conditions and the operating environment.

The present disclosure provides a voltage detection circuit provided in a semiconductor memory device, the circuit comprising a control unit configured to detect the startup voltage level of the semiconductor memory device based on the results of a ZQ calibration performed in the semiconductor memory device.

Another aspect of the present disclosure provides a semiconductor memory device comprising the voltage detection circuit described above.

Furthermore, another aspect of the present disclosure provides a method for controlling a semiconductor memory device, the method comprising: detecting, by a control unit of a voltage detection circuit provided in the semiconductor memory device detects the startup voltage level of the semiconductor memory device based on the results of a ZQ calibration performed in the semiconductor memory device.

According to the voltage detection circuit, the semiconductor memory device, and the control method of the semiconductor memory device of the present disclosure, variations in the startup voltage level of the semiconductor memory device that are caused by factors such as manufacturing variations and fluctuations in operating conditions can be suppressed.

### BRIEF DESCRIPTION OF THE DRAWINGS

The present disclosure can be more fully understood by reading the subsequent detailed description and examples with references made to the accompanying drawings, wherein:

FIG. 1 is a block diagram illustrating a configuration example of a semiconductor memory device according to an embodiment of the present disclosure;

FIG. 2 is a circuit diagram illustrating a configuration example of a code selection unit;

FIG. 3 is a circuit diagram illustrating a configuration example of a detection unit;

FIGS. 4A and 4B are timing charts illustrating voltage transitions over time for a power supply voltage, a voltage level detection signal, and various nodes within the detection unit;

FIGS. 5A and 5B are timing charts illustrating voltage transitions over time for a power supply voltage, a voltage level detection signal, and various nodes within the detection unit;

FIG. 6 is a timing chart illustrating voltage transitions over time for various signals within the semiconductor memory device;

FIG. 7 is a timing chart illustrating voltage transitions over time for various signals within the semiconductor memory device; and

FIG. 8 is a diagram illustrating another configuration example of the detection unit.

### DETAILED DESCRIPTION

The following description is made for the purpose of illustrating the general principles of the disclosure and should not be taken in a limiting sense. The scope of the disclosure is best determined by reference to the appended claims.

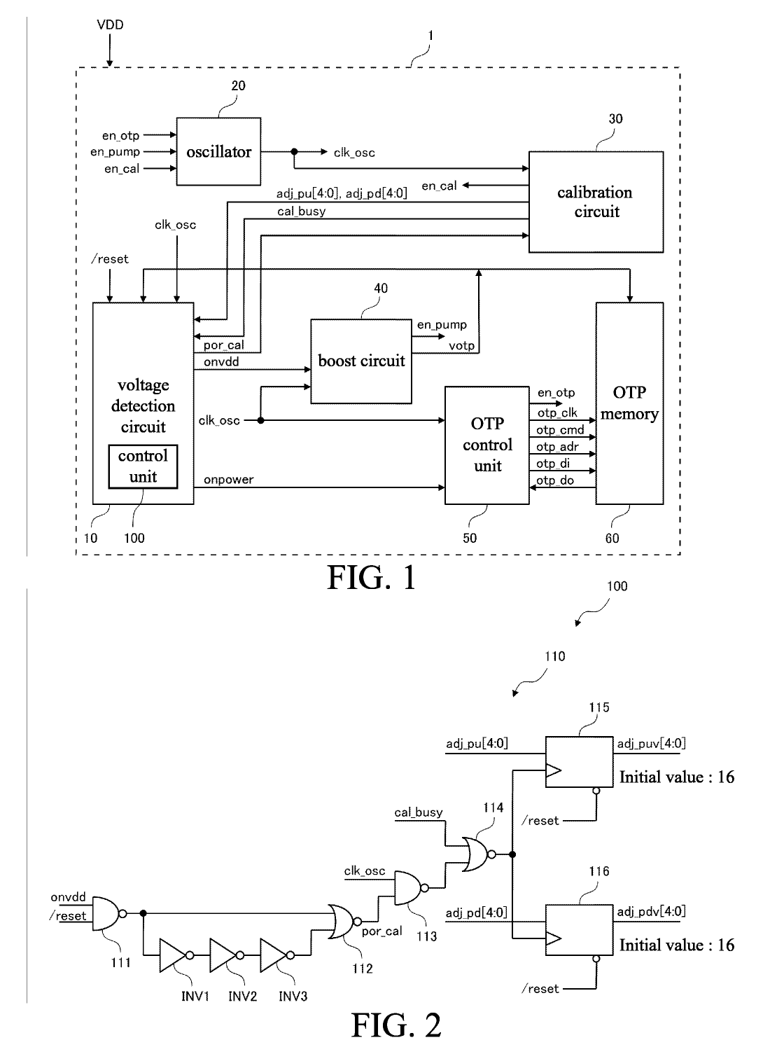

FIG. 1 is a block diagram illustrating a configuration example of a semiconductor memory device 1 according to an embodiment of the present disclosure. The semiconductor memory device 1 of the present embodiment may be, for example, a DRAM such as a Double-Data-Rate 4 Synchronous Dynamic Random Access Memory (DDR4 SDRAM). In this embodiment, the semiconductor memory device 1 includes a voltage detection circuit 10, an oscillator 20, a calibration circuit 30, a boost circuit 40, an OTP (One Time Programmable) control unit 50, and an OTP memory 60. Furthermore, as illustrated in FIG. 1, the voltage detection circuit 10 includes a control unit 100. It is noted that, for simplicity of explanation, other well-known components of the semiconductor memory device 1 (e.g., a memory cell array, power supply circuits, a command decoder, a clock generator, etc.) are not shown.

In the present embodiment, the voltage detection circuit 10 is configured to detect the external power supply voltage VDD. The voltage detection circuit is further configured to assert a trigger signal on_vdd to initiate a startup operation of the semiconductor memory device 1 when the external power supply voltage VDD reaches a predetermined startup voltage level. Additionally, the voltage detection circuit boutputs a signal on_power to the OTP control unit 50 to instruct the OTP control unit 50 to access the OTP memory 60.

The oscillator 20 is configured to generate a predetermined clock signal clk_osc. The oscillator 20 is also configured to receive a signal en_cal output from the calibration circuit 30, a signal en_pump output from the boost circuit 40, and a signal en_otp output from the OTP control unit 50. The oscillator 20 is activated when any one of these signals en_cal, en_pump, or en_otp is asserted, whereupon it generates the clock signal clk_osc and outputs it to the voltage detection circuit 10, the calibration circuit 30, the boost circuit 40, and the OTP control unit 50.

The calibration circuit 30 is configured to perform a ZQ calibration operation. In the present embodiment, upon receiving an asserted signal por_cal (described hereinafter) from the voltage detection circuit 10, the calibration circuit 30 outputs an asserted signal en_cal to the oscillator 20 and is configured to perform the ZQ calibration operation (including a pull-up calibration and a pull-down calibration) in accordance with the clock signal clk_osc output from the oscillator 20.

In the present embodiment, while the ZQ calibration operation is being performed, the calibration circuit 30 asserts a signal cal_busy, which indicates the execution status of the ZQ calibration operation, and outputs this signal to the voltage detection circuit 10. Furthermore, upon completion of the ZQ calibration operation, the calibration circuit 30 outputs a pull-up calibration code adj_pu[4:0], representing the result of the pull-up calibration, and a pull-down calibration code adj_pd[4:0], representing the result of the pull-down calibration, to the voltage detection circuit 10.

The boost circuit 40 is configured to boost a power supply voltage to generate a voltage votp. For example, upon receiving an asserted trigger signal on_vdd from the voltage detection circuit 10, the boost circuit 40 outputs an asserted signal en_pump to the oscillator 20. In accordance with the clock signal clk_osc output from the oscillator 20, the boost circuit 40 boosts the power supply voltage (in this instance, the external power supply voltage VDD) and outputs the resulting boosted voltage as the voltage votp (where votp > VDD) to the voltage detection circuit 10 and the OTP memory 60. The boost circuit 40 may be implemented as a charge pump circuit.

The maximum boost ratio of the power supply voltage in a typical boost circuit 40 can be set to a predetermined value (e.g., three, meaning three times the power supply voltage). In this context, if the trigger signal on_vdd is asserted while the power supply voltage (the external power supply voltage VDD) is low, the boosted voltage votp may not reach a level sufficient to read information stored in the OTP memory 60, even if the power supply voltage is boosted to its maximum ratio by the boost circuit 40. Therefore, it is necessary to control the assertion of the trigger signal on_vdd to occur at a time when the power supply voltage has reached an appropriate level.

The OTP control unit 50 is configured to perform read and write operations on the OTP memory 60. For example, upon receiving an asserted signal on_power from the voltage detection circuit 10, the OTP control unit 50 outputs an asserted signal en_otp to the oscillator 20 and executes read and write operations on the OTP memory 60 in accordance with the clock signal clk_osc output from the oscillator 20. Here, the read and write operations on the OTP memory 60 may be performed by transmitting a clock signal otp_clk, a command signal otp_cmd, an address signal otp_adr, and an input data signal otp_di from the OTP control unit 50 to the OTP memory 60, and by transmitting an output data signal otp_do from the OTP memory 60 to the OTP control unit 50. Furthermore, the input data signal otp_di may be input to the OTP control unit 50 from outside the semiconductor memory device 1 via a command decoder (not shown), and the output data signal otp_do may be output from the OTP control unit 50 to the outside of the semiconductor memory device 1 via the command decoder (not shown).

The OTP memory 60 is configured to store initial setting information for configuring operating conditions of the semiconductor memory device 1 (e.g., an internal operating voltage of the semiconductor memory device 1). The OTP memory 60 is also configured to be activated by the voltage votp, which is boosted by the boost circuit 40. The OTP memory 60 may be implemented using a non-volatile storage device, for example, an OTP ROM (One Time Programmable ROM) such as a fuse ROM (Read Only Memory), laser fuses, or other types of non-volatile memory.

Next, a configuration of the control unit 100 of the voltage detection circuit 10 will be described. In the present embodiment, the control unit 100 is configured to detect the startup voltage level of the semiconductor memory device 1 based on the results of a predetermined calibration (in the present embodiment, a ZQ calibration) performed in the semiconductor memory device 1.

Furthermore, the control unit 100 may detect the startup voltage level of the semiconductor memory device 1 by adjusting the impedance of a circuit (in the present embodiment, a detection unit 120 described hereinafter) that includes at least one element, based on the result of the ZQ calibration. Thereby, it becomes possible to easily detect the startup voltage level of the semiconductor memory device 1 based on the impedance of the circuit that was adjusted based on the ZQ calibration result.

The circuit may be provided in the control unit 100. This enables the startup voltage level of the semiconductor memory device 1 to be easily detected within the control unit 100.

Moreover, the control unit 100 may detect the startup voltage level of the semiconductor memory device 1 by adjusting the impedance of the circuit, using as an initial value any value within a range of values of the calibration code that indicates the result of the ZQ calibration. This makes it possible to adjust the impedance of the circuit after the impedance of the circuit has been initialized based on the initial value.

Additionally, the control unit 100 may detect the startup voltage level of the semiconductor memory device 1 based on the result of the predetermined calibration in the semiconductor memory device 1 when the external power supply voltage VDD reaches a predetermined value (e.g., a voltage level at which the predetermined calibration, such as the ZQ calibration, is performed). This enables the detection of the startup voltage level of the semiconductor memory device 1 as a result of the predetermined calibration having been performed.

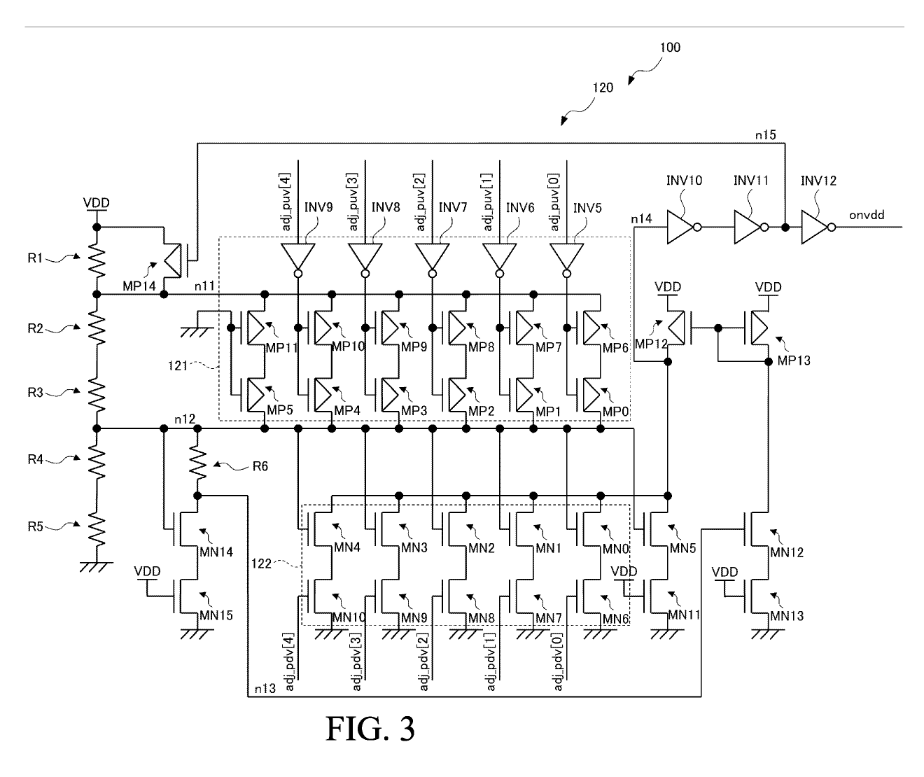

In the present embodiment, the control unit 100 includes a selection unit 110, illustrated in FIG. 2, and a detection unit 120, illustrated in FIG. 3. The selection unit 110 is configured to select either the preset initial value of a calibration code, or the value of the calibration code indicating the result of the ZQ calibration from the calibration circuit 30. Furthermore, the detection unit 120 is configured to detect the startup voltage level of the semiconductor memory device 1 (that is, the level of the power supply voltage at which the trigger signal on_vdd is asserted) based on the calibration code value selected by the selection unit 110.

Referring to FIG. 2, a configuration example of the selection unit 110 in the present embodiment will be described. The selection unit 110 includes: three inverter circuits INV1, INV2, and INV3, which constitute a delay unit; two NAND circuits 111 and 113; two NOR circuits 112 and 114; and two D flip-flop circuits 115 and 116. While the present embodiment is described using an example wherein the delay unit is configured using three inverter circuits INV1, INV2, and INV3, the delay unit may be configured using a different number of inverter circuits, or the delay unit may be configured using other circuits or elements different from inverter circuits.

As illustrated in FIG. 2, the trigger signal on_vdd is input to a first input terminal of the NAND circuit 111, and a signal /reset is input to a second input terminal of the NAND circuit 111. The three inverter circuits INV1, INV2, and INV3 are connected in series, and an output signal of the NAND circuit 111 is input to an input terminal of the inverter circuit INV1. In the present embodiment, a delay time of the delay unit (in this embodiment, the inverter circuits INV1, INV2, and INV3) is designed to be longer than a duration of the ZQ calibration. The output signal of the NAND circuit 111 is input to a first input terminal of the NOR circuit 112, and an output signal of the inverter circuit INV3 is input to a second input terminal of the NOR circuit 112.

The clock signal clk_osc is input to a first input terminal of the NAND circuit 113, and the output signal por_cal of the NOR circuit 112 is input to a second input terminal of the NAND circuit 113.

The signal cal_busy is input to a first input terminal of the NOR circuit 114, and the output signal of the NAND circuit 113 is input to a second input terminal of the NOR circuit 114.

The pull-up calibration code adj_pu[4:0] is input to the D terminal of the D flip-flop circuit 115, the signal /reset is input to the reset terminal of the D flip-flop circuit 115, and the output signal of the NOR circuit 114 is input to the clock terminal of the D flip-flop circuit 115. Furthermore, the pull-down calibration code adj_pd[4:0] is input to the D terminal of the D flip-flop circuit 116, the signal /reset is input to the reset terminal of the D flip-flop circuit 116, and the output signal of the NOR circuit 114 is input to the clock terminal of the D flip-flop circuit 116.

In the selection unit 110 configured as described above, when the signal /reset is negated (e.g., transitions to a low level), an initial value (in this example, 16) for the pull-up calibration code adj_puv[4:0] is set in the D flip-flop circuit 115, and an initial value (in this example, 16) for the pull-down calibration code adj_pdv[4:0] is set in the D flip-flop circuit 116. Although 16 is used as an example in the present embodiment, a value other than 16 may be set as the initial value. The signal /reset may be a signal input via an external command when external power is applied to the semiconductor memory device 1. Furthermore, the trigger signal on_vdd input to the selection unit 110 may be the trigger signal on_vdd output from the detection unit 120, or it may be a trigger signal on_vdd output from another voltage detection circuit (not shown) different from the detection unit 120.

When the initial values are set in the two D flip-flop circuits 115 and 116, the selection unit 110 outputs the initialized pull-up calibration code adj_puv[4:0] and pull-down calibration code adj_pdv[4:0] to the detection unit 120. Thereby, as will be described later, the detection unit 120 performs a detection process for the startup voltage of the semiconductor memory device 1. In this detection process, if the trigger signal on_vdd is asserted, and furthermore, the signal /reset is asserted, the signal por_cal is asserted, thereby initiating a calibration in the control unit 100 (referred to herein as "POR (Power On Reset) calibration").

When the POR calibration is initiated, the oscillator 20 is activated, and the clock signal clk_osc is toggled. The calibration circuit 30 performs the ZQ calibration. While the ZQ calibration is being performed, the signal cal_busy is asserted, which prevents the values held in the two D flip-flop circuits 115 and 116 from being updated. When the ZQ calibration is completed, the signal cal_busy is negated. The value of the pull-up calibration code adj_pu[4:0] output from the calibration circuit 30 is set in the D flip-flop circuit 115 in response to the toggling of the clock signal clk_osc, and the value of the pull-down calibration code adj_pd[4:0] output from the calibration circuit 30 is set in the D flip-flop circuit 116 in response to the toggling of the clock signal clk_osc. In this manner, the values held in the two D flip-flop circuits 115 and 116 are updated.

When the transfer of the pull-up calibration code adj_pu[4:0] and the pull-down calibration code adj_pd[4:0] from the calibration circuit 30 to the selection unit 110 is completed, the assertion information of the trigger signal on_vdd, which has propagated through the delay unit (in this embodiment, inverter circuits INV1, INV2, and INV3), is output from the inverter circuit INV3. This causes the signal por_cal to be negated. Thereby, even if the clock signal clk_osc toggles, or if the calibration circuit 30 updates the pull-up calibration code adj_pu[4:0] or the pull-down calibration code adj_pd[4:0], the two D flip-flop circuits 115 and 116 are able to continue holding the set values without updating them.

Next, referring to FIG. 3, a configuration example of the detection unit 120 according to the present embodiment will be described. The detection unit 120 includes a plurality of resistor elements R1 to R6, a plurality of inverter circuits INV5 to INV12, a plurality of PMOS transistors (PMOS FETs) MP0 to MP14, and a plurality of NMOS transistors (NMOS FETs) MN0 to MN15. The detection unit 120 is configured to detect the startup voltage of the semiconductor memory device 1 by adjusting the impedance based on the result of the ZQ calibration in the calibration circuit 30. Here, the detection unit 120 is an example of the "circuit" of the present disclosure.

Furthermore, the detection unit 120 includes: a pull-up calibration unit 121 that performs a pull-up calibration for the POR calibration based on the result of the ZQ calibration in the calibration circuit 30; and a pull-down calibration unit 122 that performs a pull-down calibration for the POR calibration based on the result of the ZQ calibration in the calibration circuit 30.

The five resistor elements R1 to R5 are connected in series between a high power supply voltage (voltage VDD) and a low power supply voltage (ground voltage).

The pull-up calibration unit 121 includes a plurality of PMOS transistors MP0 to MP11 and a plurality of inverter circuits INV5 to INV9. Gate terminals (control terminals) of each PMOS transistor MPi (where i is an integer from 0 to 4) and PMOS transistor MP(i+6) are connected to an output terminal of the inverter circuit INV(i+5), and gate terminals of each of the PMOS transistor MP5 and the PMOS transistor MP11 are connected to the low power supply voltage. The pull-up calibration code adj_puv[i] is input to the inverter circuit INV(i+5). Furthermore, a source terminal of the PMOS transistor MP(j+6) (where j is an integer from 0 to 5) is connected to a node n11 between the resistor element R1 and the resistor element R2. A drain terminal of the PMOS transistor MP(j+6) is connected to a source terminal of the PMOS transistor MPj (that is, respective channels of the PMOS transistor MPj and the PMOS transistor MP(j+6) are connected in series). Additionally, a drain terminal of the PMOS transistor MPj is connected to a node n12 between the resistor element R3 and the resistor element R4.

The gate terminals of each of the PMOS transistor MPi and the PMOS transistor MP(i+6) are configured to receive a corresponding 1-bit signal (a logically inverted signal of the pull-up calibration code adj_puv[i]) of the pull-up calibration code adj_puv[4:0], which represents the result of the ZQ calibration. Here, each of the PMOS transistor MPi and the PMOS transistor MP(i+6) is an example of a "first transistor unit" of the present disclosure. Moreover, the PMOS transistor MP(i+6) is an example of a "first transistor" of the present disclosure, and the PMOS transistor MPi is an example of a "second transistor" of the present disclosure.

The pull-down calibration unit 122 includes a plurality of NMOS transistors MN0 to MN10. Gate terminals (control terminals) of each of the NMOS transistors MNk (where k is an integer from 0 to 4) are connected to the node n12. The pull-down calibration code adj_pdv[k] is input to the respective gate terminals of the NMOS transistors MN(k+6). Furthermore, drain terminals of the NMOS transistors MNk are connected to a drain terminal of the NMOS transistor MN5. Source terminals of the NMOS transistors MNk are connected to drain terminals of the NMOS transistors MN(k+6) (that is, the respective channels of the NMOS transistors MNk and the NMOS transistors MN(k+6) are connected in series). Additionally, source terminals of the NMOS transistors MN(k+6) are connected to the low voltage power supply.

The gate terminals of each of the NMOS transistors MN(k+6) are configured to receive a corresponding 1-bit signal (the pull-down calibration code adj_pdv[k]) of the pull-down calibration code adj_pdv[4:0], which represents the result of the ZQ calibration. Here, each of the NMOS transistor MNk and the NMOS transistor MN(k+6) is an example of a "second transistor unit" of the present disclosure. Moreover, the NMOS transistor MN(k+6) is an example of a "third transistor" of the present disclosure, and the NMOS transistor MNk is an example of a "fourth transistor" of the present disclosure.

A source terminal of the PMOS transistor MP12 is connected to the high voltage power supply, and a drain terminal of the PMOS transistor MP12 is connected to the drain terminal of the NMOS transistor MN5. A gate terminal of the PMOS transistor MP12 is connected to a gate terminal of the PMOS transistor MP13. Furthermore, a source terminal of the PMOS transistor MP13 is connected to the high voltage power supply, and a drain terminal of the PMOS transistor MP13 is connected to a drain terminal of the NMOS transistor MN12. Additionally, the gate terminal of the PMOS transistor MP13 is connected to the drain terminal of the PMOS transistor MP13 (i.e., diode-connected).

A gate terminal of the NMOS transistor MN5 is connected to the node n12, and a source terminal of the NMOS transistor MN5 is connected to a drain terminal of the NMOS transistor MN11. Furthermore, a gate terminal of the NMOS transistor MN11 is connected to the high voltage power supply, and a source terminal of the NMOS transistor MN11 is connected to the low voltage power supply.

A gate terminal of the NMOS transistor MN12 is connected to a node n13, which is between the resistor element R6 and a drain terminal of the NMOS transistor MN14. A source terminal of the NMOS transistor MN12 is connected to a drain terminal of the NMOS transistor MN13. Furthermore, a gate terminal of the NMOS transistor MN13 is connected to the high voltage power supply, and a source terminal of the NMOS transistor MN13 is connected to the low voltage power supply.

The three inverter circuits INV10 to INV12 are connected in series. An input terminal of the inverter circuit INV10 is connected to a node n14, which is between the drain terminal of the PMOS transistor MP12 and the drain terminal of the NMOS transistor MN5. The inverter circuit INV12 outputs the trigger signal on_vdd.

A node n15, located between the inverter circuit INV11 and the inverter circuit INV12, is connected to a gate terminal of the PMOS transistor MP14. A source terminal of the PMOS transistor MP14 is connected to the high voltage power supply, and a drain terminal of the PMOS transistor MP14 is connected to the node n11.

One end of the resistor element R6 is connected to the node n12, and the other end of the resistor element R6 is connected to the drain terminal of the NMOS transistor MN14. A gate terminal of the NMOS transistor MN14 is connected to the node n12, and a source terminal of the NMOS transistor MN14 is connected to a drain terminal of the NMOS transistor MN15. Furthermore, a gate terminal of the NMOS transistor MN15 is connected to the high voltage power supply, and a source terminal of the NMOS transistor MN15 is connected to the low voltage power supply.

In the detection unit 120 configured as described above, the trigger signal on_vdd is generated by comparing the voltage at the node n12 with the voltage at the node n13. For example, when the external power supply voltage VDD becomes sufficiently high, the NMOS transistor MN14 enters an ON state, causing the voltage at the node n13 to decrease. As a result, the potential at the node n14 changes from a high level to a low level, causing the trigger signal on_vdd to transition to a high level. Furthermore, the signal at the node n15 (which is a logically inverted version of the trigger signal on_vdd) is fed back to the node n11 to perform hysteresis control. This hysteresis control sets the voltage at which the trigger signal on_vdd is negated lower than the voltage at which it is asserted. This makes it possible to suppress frequent toggling of the trigger signal on_vdd if the voltage VDD fluctuates near the assertion voltage due to noise or the circuit's current consumption.

Furthermore, the detection unit 120 optimizes the startup voltage of the semiconductor memory device 1 (i.e., the voltage VDD at which the trigger signal on_vdd is asserted) by adjusting the impedances of the pull-up calibration unit 121 and the pull-down calibration unit 122 based on the result of the ZQ calibration (that is, the values of the pull-up calibration code adj_puv[4:0] and the pull-down calibration code adj_pdv[4:0]).

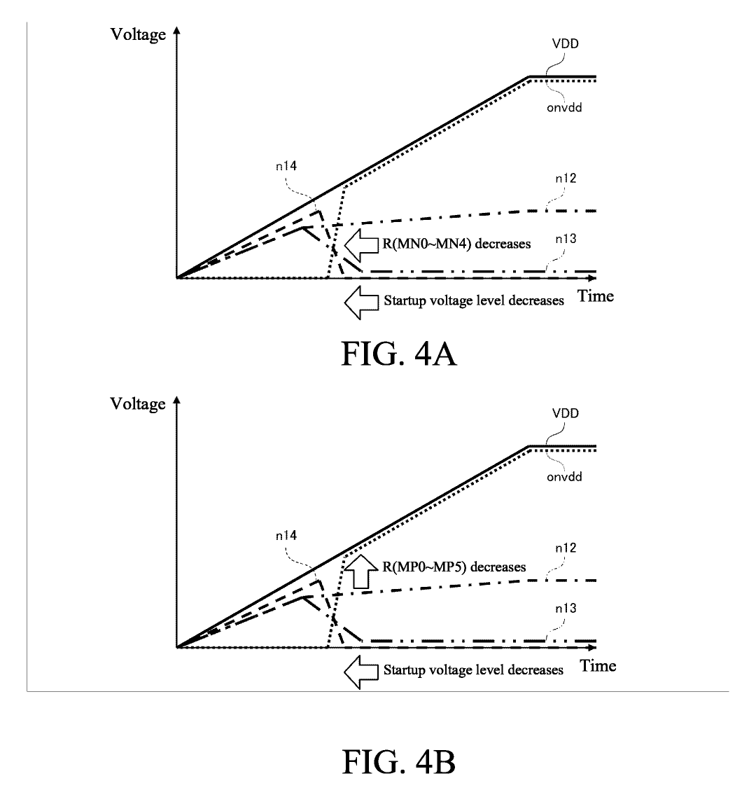

Here, referring to FIG. 4, an example of the relationship between the startup voltage level of the semiconductor memory device 1 and the resistances of the respective MOS transistors of the pull-up calibration unit 121 and the pull-down calibration unit 122 will be described. First, as illustrated in FIG. 4A, as the ON-resistance (R(MN0-MN4)) of the NMOS transistors MN0, MN1, MN2, MN3, and MN4 of the pull-down calibration unit 122 decreases, the voltage at the node n14 decreases. Accordingly, the startup voltage level of the semiconductor memory device 1 decreases. Furthermore, as illustrated in FIG. 4B, as the ON-resistance (R(MP0-MP4)) of the PMOS transistors MP0, MP1, MP2, MP3, and MP4 of the pull-up calibration unit 121 decreases, the voltage at the node n12 approaches the voltage VDD. As a result, the voltage VDD required for the node n14 to transition to a low level decreases. This also signifies that the startup voltage level of the semiconductor memory device 1 decreases.

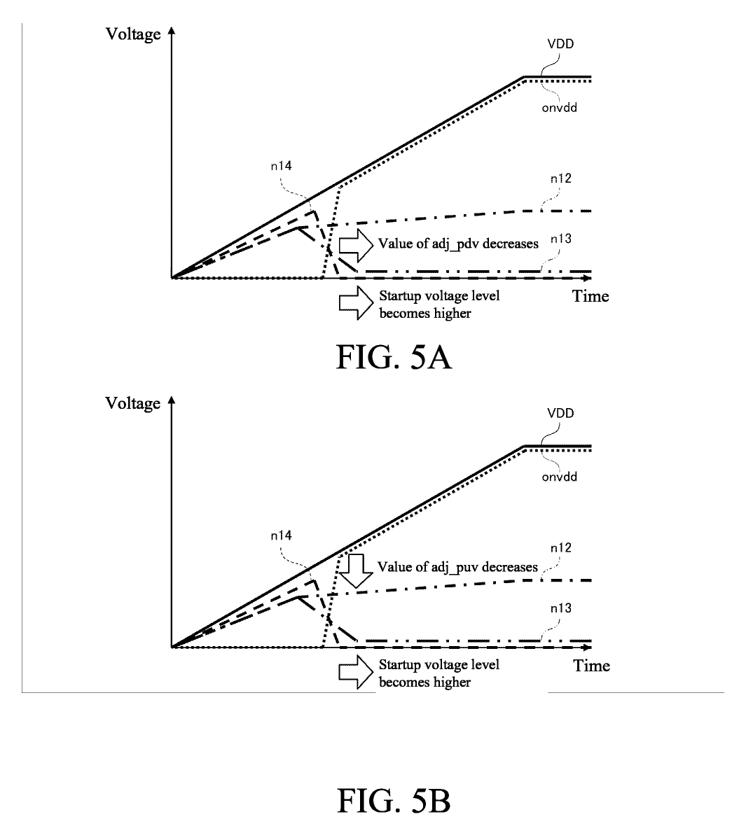

Next, referring to FIG. 5, an example of the relationship between the startup voltage level of the semiconductor memory device 1 and the values of the pull-up calibration code adj_puv[4:0] and the pull-down calibration code adj_pdv[4:0] will be described. First, as illustrated in FIG. 5A, as the value of the pull-down calibration code adj_pdv[4:0] decreases, the ON-resistance (R(MN0-MN4)) of the NMOS transistors MN0, MN1, MN2, MN3, and MN4 of the pull-down calibration unit 122 increases, thus causing the voltage at the node n14 to rise. This signifies that decreasing the value of the pull-down calibration code adj_pdv[4:0] causes the startup voltage level of the semiconductor memory device 1 to become higher. Furthermore, as illustrated in FIG. 5B, as the value of the pull-up calibration code adj_puv[4:0] decreases, the ON-resistance (R(MP0-MP4)) of the PMOS transistors MP0, MP1, MP2, MP3, and MP4 of the pull-up calibration unit 121 increases, thus causing the voltage at the node n12 to fall. This lengthens the time required for the node n14 to transition to a low level. This signifies that decreasing the value of the pull-up calibration code adj_puv[4:0] causes the startup voltage level of the semiconductor memory device 1 to become higher.

In this manner, the startup voltage level of the semiconductor memory device 1 changes in accordance with the values of the calibration codes adj_puv[4:0] and adj_pdv[4:0], which indicate the result of the ZQ calibration.

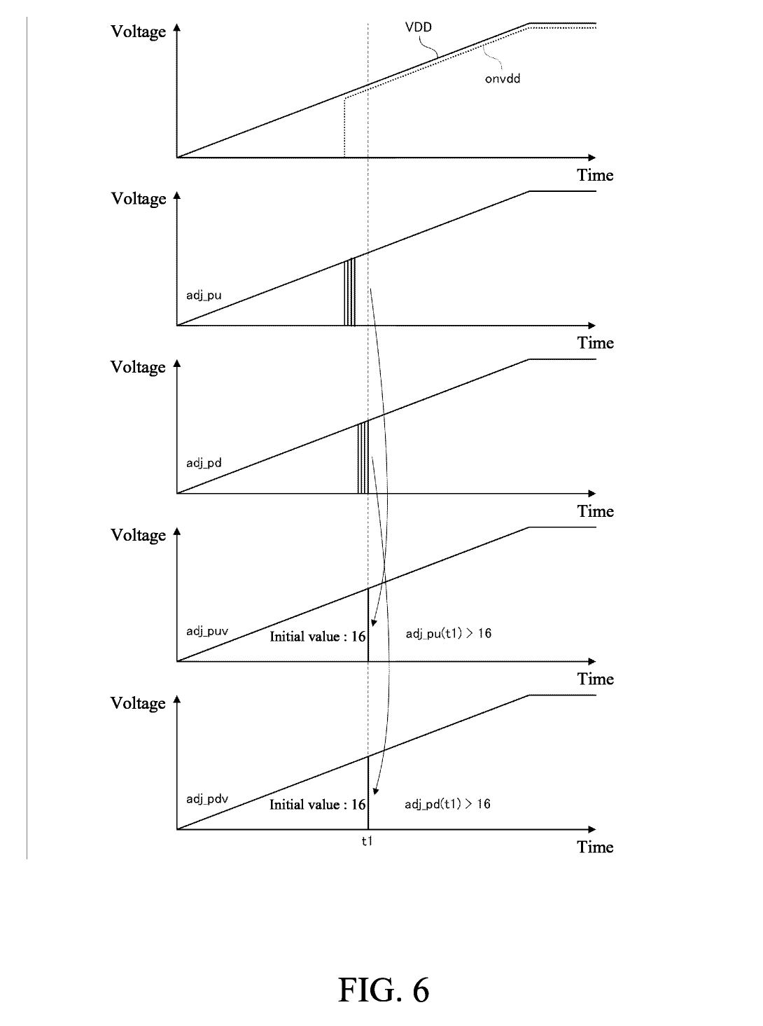

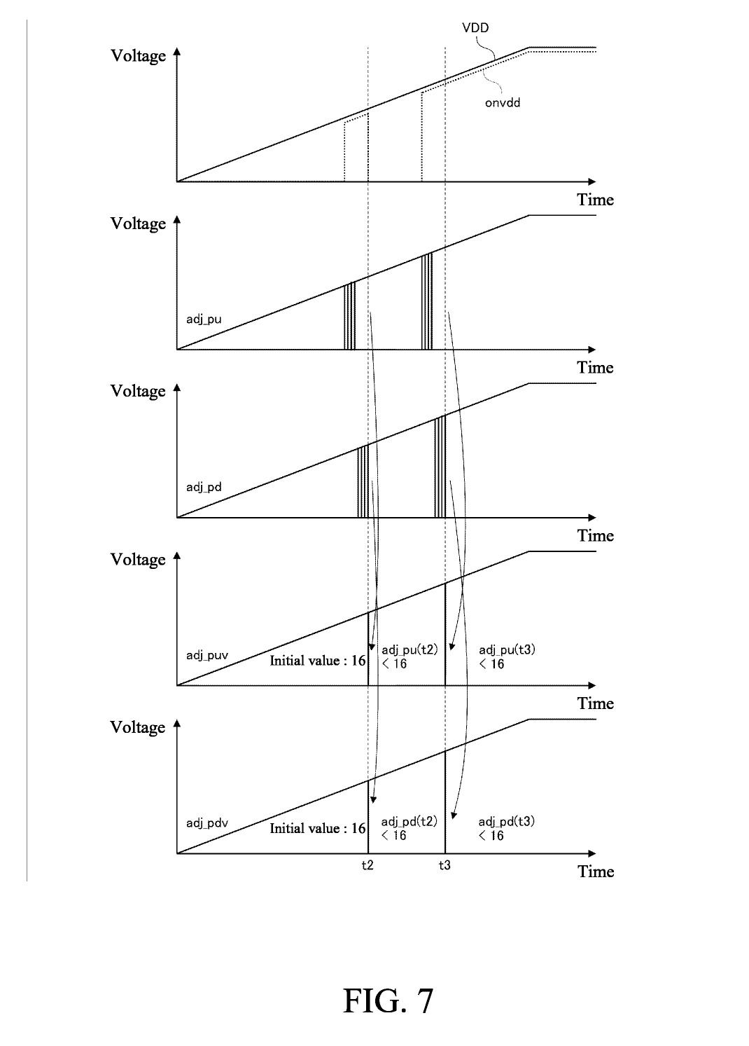

Referring to FIGS. 6 and 7, the operation of the semiconductor memory device 1 according to the present embodiment will be described. FIG. 6 is a timing chart illustrating voltage transitions over time for various signals within the semiconductor memory device 1 under conditions of slow device characteristics.

First, when power is applied to the semiconductor memory device 1, the external power supply voltage VDD gradually rises. At this time, the detection unit 120 of the control unit 100 performs startup voltage level detection using the pull-up calibration code adj_puv[4:0] and the pull-down calibration code adj_pdv[4:0] that have been set to their initial values (in this embodiment, 16). Then, when the voltage VDD reaches a predetermined level (i.e., detects the startup voltage level), the detection unit 120 of the control unit 100 outputs an asserted trigger signal on_vdd. This causes the ZQ calibration to be performed in the calibration circuit 30. In the example illustrated in FIG. 6, the pull-up calibration is performed first during the ZQ calibration, and the pull-down calibration is performed after the pull-up calibration is completed.

The result of the pull-up calibration in the calibration circuit 30 (the pull-up calibration code adj_pu[4:0]) is output from the calibration circuit 30 to the selection unit 110 of the control unit 100. The selection unit 110 then outputs the pull-up calibration code adj_puv[4:0], corresponding to the input pull-up calibration code adj_pu[4:0], to the detection unit 120. Similarly, the result of the pull-down calibration in the calibration circuit 30 (the pull-down calibration code adj_pd[4:0]) is output from the calibration circuit 30 to the selection unit 110 of the control unit 100. The selection unit 110 then outputs the pull-down calibration code adj_pdv[4:0], corresponding to the input pull-down calibration code adj_pd[4:0], to the detection unit 120.

Then, at time t1, when the pull-up calibration code adj_puv[4:0] and the pull-down calibration code adj_pdv[4:0] are input to the detection unit 120, the detection unit 120 adjusts the impedances of the pull-up calibration unit 121 and the pull-down calibration unit 122 using these input codes. Here, if the device characteristics are slow due to manufacturing variations or the like, the calibration circuit 30 outputs the pull-up calibration code adj_pu[4:0] and the pull-down calibration code adj_pd[4:0] to the control unit 100 as large values (in this embodiment, values larger than 16) such that the ON-resistance of the MOS transistors becomes smaller. In this embodiment, as was explained with reference to FIG. 5, because the pull-up calibration code adj_puv[4:0] and the pull-down calibration code adj_pdv[4:0] become larger, the startup voltage detection level in the detection unit 120 is lowered. However, because the external power supply voltage VDD is already higher than this newly adjusted startup voltage detection level, the trigger signal on_vdd is not negated. As a result, other operations of the semiconductor memory device 1 (e.g., generation of internal power supplies) are performed.

FIG. 7 is a timing chart illustrating voltage transitions over time for various signals within the semiconductor memory device 1 under conditions of fast device characteristics.

The operation up to the point at which the startup voltage detection level is adjusted at time t2, after the trigger signal on_vdd is initially asserted, is the same as the operation shown in FIG. 6. However, if the device characteristics are fast due to manufacturing variations or the like, the calibration circuit 30 outputs the pull-up calibration code adj_pu[4:0] and the pull-down calibration code adj_pd[4:0] to the control unit 100 as small values (in this embodiment, values smaller than 16) such that the ON-resistance of the MOS transistors becomes larger. In this embodiment, as was explained with reference to FIG. 5, because the pull-up calibration code adj_puv[4:0] and the pull-down calibration code adj_pdv[4:0] become smaller, the startup voltage detection level in the detection unit 120 becomes higher. For this reason, if the external power supply voltage VDD rises slowly, the trigger signal on_vdd may be temporarily negated.

Then, the detection unit 120 of the control unit 100 performs the startup voltage level detection using the pull-up calibration code adj_puv[4:0] and the pull-down calibration code adj_pdv[4:0] that were input at time t2. When the voltage VDD reaches the predetermined level (i.e., detects the startup voltage level), the detection unit 120 of the control unit 100 again outputs an asserted trigger signal on_vdd. This causes the ZQ calibration to be performed again in the calibration circuit 30.

At time t3, when the pull-up calibration code adj_puv[4:0] and the pull-down calibration code adj_pdv[4:0] are input to the detection unit 120, the detection unit 120 adjusts the impedances of the pull-up calibration unit 121 and the pull-down calibration unit 122 using these input codes. Thereby, the startup voltage detection level in the detection unit 120 is adjusted again. Here, if the external environment has not changed significantly since the previous calibration, the values of the pull-up calibration code adj_puv[4:0] and the pull-down calibration code adj_pdv[4:0] input at time t3 will be substantially the same as the previous values (the values input at time t2). For this reason, the trigger signal on_vdd is not negated, and other operations of the semiconductor memory device 1 (e.g., generation of internal power supplies) are performed.

As described above, according to the voltage detection circuit 10, the semiconductor memory device 1, and the control method thereof of the present embodiment, the startup voltage level is detected based on the result of a calibration that accounts for the effects of variations in manufacturing conditions and the operating environment of the semiconductor memory device 1. Consequently, it is possible to suppress variations in the startup voltage level of the semiconductor memory device 1 that are attributable to such factors.

The embodiments described above have been presented to facilitate understanding of the present disclosure and are not intended to limit the scope of the present disclosure. Accordingly, each element disclosed in the above embodiments is intended to include all design changes and equivalents that fall within the technical scope of the present disclosure.

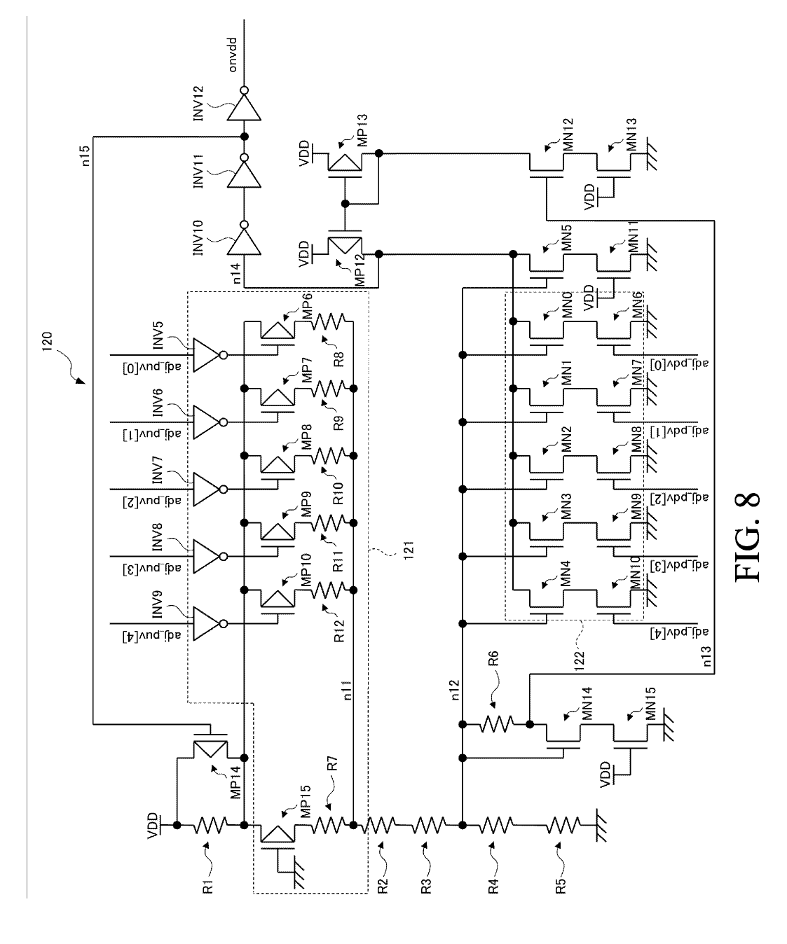

For example, although the embodiments described above were explained using an example in which the pull-up calibration unit 121 includes the PMOS transistors MP0 to MP4, the present disclosure is not limited to this embodiment. For instance, as illustrated in FIG. 8, the pull-up calibration unit 121 may include resistor elements R8 to R12 in place of the PMOS transistors MP0 to MP4. Furthermore, the pull-up calibration unit 121 may include a PMOS transistor MP15 and a resistor element R7 between the resistor element R1 and the resistor element R2. In this embodiment, similar to the embodiments described above, it is possible to suppress variations in the startup voltage level of the semiconductor memory device 1 that are caused by factors including variations in manufacturing conditions and the operating environment.

Furthermore, although the embodiments described above were explained using an example in which the pull-down calibration unit 122 includes the NMOS transistors MN0 to MN4, the present disclosure is not limited to this embodiment. For example, the pull-down calibration unit 122 may include resistor elements in place of the NMOS transistors MN0 to MN4. In this embodiment as well, it is possible to suppress variations in the startup voltage level of the semiconductor memory device 1 that are caused by factors including variations in manufacturing conditions and the operating environment.

Moreover, although the embodiments described above were explained using an example in which the semiconductor memory device is a DRAM, the present disclosure is not limited to this embodiment. For example, the semiconductor memory device may be an SRAM (Static Random Access Memory), a pSRAM (pseudo-Static Random Access Memory), a flash memory, or another type of semiconductor memory device.

Additionally, the respective configurations of the voltage detection circuit 10 and the control unit 100 shown in FIG. 1, the selection unit 110 shown in FIG. 2, and the detection unit 120 shown in FIGS. 3 and 8 are merely examples, and may be modified as appropriate, or well-known configurations or various other configurations may be adopted.

What is claimed is:

1. A voltage detection circuit provided in a semiconductor memory device, comprising:
a control unit configured to detect a startup voltage level of the semiconductor
memory device based on a result of a ZQ calibration performed in the semiconductor memory device.

2. The voltage detection circuit according to claim 1, wherein the startup voltage level varies in accordance with a value of a calibration code indicating the result of the ZQ calibration.

3. The voltage detection circuit according to claim 2, wherein the startup voltage level becomes higher as a value of a pull-up calibration code, which indicates the result of the ZQ calibration, becomes smaller.

4. The voltage detection circuit according to claim 2, wherein the startup voltage level becomes higher as a value of a pull-down calibration code, which indicates the result of the ZQ calibration, becomes smaller.

5. The voltage detection circuit according to claim 1, wherein the control unit is configured to detect the startup voltage level of the semiconductor memory device by adjusting an impedance of a circuit, which includes at least one element, based on the result of the ZQ calibration.

6. The voltage detection circuit according to claim 5, wherein the circuit comprises at least one of the following:
a pull-up calibration unit configured to perform a pull-up calibration based on the result of the ZQ calibration; and
a pull-down calibration unit configured to perform a pull-down calibration based on the result of the ZQ calibration.

7. The voltage detection circuit according to claim 6, wherein the circuit comprises the pull-up calibration unit, and wherein the pull-up calibration unit comprises at least one first transistor unit configured to receive a corresponding one-bit signal of at least one bit representing the result of the ZQ calibration,
wherein the first transistor unit comprises a first transistor and a second transistor, each having a control terminal configured to receive the corresponding one-bit signal, and
wherein respective channels of the first transistor and the second transistor are connected in series.

8. The voltage detection circuit according to claim 6, wherein the circuit comprises the pull-up calibration unit, and wherein the pull-up calibration unit comprises at least one first transistor unit configured to receive a corresponding one-bit signal of at least one bit representing the result of the ZQ calibration,
wherein the first transistor unit comprises:
a first transistor having a control terminal configured to receive the corresponding one-bit signal; and
a resistor element connected in series with a channel of the first transistor.

9. The voltage detection circuit according to claim 6, wherein the circuit comprises the pull-down calibration unit, and wherein the pull-down calibration unit comprises at least one second transistor unit configured to receive a corresponding one-bit signal of at least one bit representing the result of the ZQ calibration,
wherein the second transistor unit comprises: a third transistor having a control terminal configured to receive the corresponding one-bit signal; and a fourth transistor having a channel connected in series with a channel of the third transistor.

10. The voltage detection circuit according to claim 5, wherein the circuit is provided in the control unit.

11. The voltage detection circuit according to claim 5, wherein the control unit is configured to detect the startup voltage level of the semiconductor memory device by adjusting the impedance of the circuit, using any value within a value range of a calibration code that indicates the result of the ZQ calibration as an initial value.

12. The voltage detection circuit according to claim 1, wherein the control unit is configured to detect the startup voltage level of the semiconductor memory device based on the result of the ZQ calibration performed in the semiconductor memory device, when a voltage of an external power supply reaches a predetermined value.

13. A semiconductor memory device, comprising:
a calibration circuit configured to perform a predetermined calibration operation in the semiconductor memory device and to output a calibration result; and
a voltage detection circuit, wherein the voltage detection circuit includes a control unit configured to detect the startup voltage level of the semiconductor memory device based on the calibration result,
and the control unit includes:
a selection unit configured to select a calibration code from among the calibration result and a predetermined initial value; and
a detection unit coupled to the selection unit and configured to receive the calibration code,
wherein the detection unit is configured to detect the startup voltage level of the semiconductor memory device by adjusting an internal impedance thereof based on the calibration code, and to output a trigger signal when an external power supply voltage reaches the startup voltage level.

14. The semiconductor memory device according to claim 13, wherein the detection unit includes a pull-up calibration unit,
wherein the pull-up calibration unit includes a plurality of first transistor units,
wherein each of the plurality of first transistor units includes a first transistor and a second transistor having channels connected in series with each other, and
wherein control terminals of the first transistor and the second transistor are configured to be controlled based on a corresponding bit of a pull-up calibration code, the pull-up calibration code being part of the calibration code, to adjust an impedance of a pull-up path of the detection unit.

15. The semiconductor memory device according to claim 13, wherein the detection unit includes a pull-down calibration unit,
wherein the pull-down calibration unit includes a plurality of second transistor units,
wherein each of the plurality of second transistor units includes a third transistor and a fourth transistor having channels connected in series with each other, and
wherein control terminals of the third transistor and the fourth transistor are configured to be controlled based on a corresponding bit of a pull-down calibration code, the pull-down calibration code being part of the calibration code, to adjust an impedance of a pull-down path of the detection unit.

16. The semiconductor memory device according to claim 13, wherein the startup voltage level varies in accordance with a value of the calibration code, and the startup voltage level becomes higher as the value of the calibration code becomes smaller.

17. The semiconductor memory device according to claim 13,
wherein the selection unit is configured to:
initially select the predetermined initial value as the calibration code after the semiconductor memory device receives power, and supply the predetermined initial value for an initial startup voltage level detection by the detection unit; and
after the calibration circuit completes the predetermined calibration operation and outputs the calibration result, select a calibration code based on the calibration result to update the calibration code used by the detection unit.

18. The semiconductor memory device according to claim 13, wherein the detection unit further includes a feedback path coupled from a point on a path that generates the trigger signal to another point inside the detection unit,
wherein the feedback path is configured to provide hysteresis control for the trigger signal to suppress frequent inversions of the trigger signal due to noise when the external power supply voltage is near the startup voltage level.

19. A method for controlling a semiconductor memory device, the method comprising:
detecting, by a control unit of a voltage detection circuit provided in the semiconductor memory device to detect the startup voltage level of the semiconductor memory device based on a result of a ZQ calibration performed in the semiconductor memory device.

20. The method according to claim 19, wherein the startup voltage level varies in accordance with a value of a calibration code indicating the result of the ZQ calibration.
